(19) United States
(12) Patent Application Publication
(10) Pub. No.: US 2012/0261172 A1
(43) Pub. Date: Oct. 18, 2012

(54) STRUCTURE AND PATTERN FORMING METHOD OF TRANSPARENT CONDUCTIVE CIRCUIT

(76) Inventor: Yung-Shu YANG, Taipei City (TW)

(21) Appl. No.: 13/213,704

(22) Filed: Aug. 19, 2011

(30) Foreign Application Priority Data
Apr. 14, 2011 (TW) 100112907

(51) Int. Cl. H05K 1/09; H05K 3/02; B05D 5/12; C08J 7/18

(52) U.S. Cl. 174/257; 427/553; 427/98.5; 427/98.4; 427/75

(57) ABSTRACT

A structure and manufacturing method of transparent conductive circuits, comprises a base material, ink layer provided with absorbing polymer liquid characteristics and a conductive layer composed of a conductive polymer coating. The ink layer is attached to the areas on the surface of the base material not requiring electrical conductivity, and heat energy or radiation is used to accelerate drying and hardening of the ink layer. The conductive layer with an area larger than that of the ink layer is attached to and contacts the ink layer, thereby enabling the ink layer attached to the surface of the base material to increase electrical resistivity of conductive layer in contact therewith. The areas relative to the conductive layer on the surface of the base material not in contact with the ink layer are provided with electrical conductivity. Accordingly, the required conductive circuits or patterns are formed on the base material.

### BACKGROUND OF THE INVENTION

(a) Field of the Invention

The present invention relates to a structure and manufacturing/pattern forming method of transparent conductive circuit, which is applied by using ink layer attached to the surface of a base material to increase the electrical resistivity of conductive layer in contact therewith, to the extent of being non-conductive. The areas relative to the ink layer on the surface of the transparent base material which is not in contact with the conductive layer are provided with electrical conductivity. Accordingly, the required conductive circuits or patterns are formed on the transparent base material. In addition, the present invention is further applied by using a removal fluid provided with polar characteristics to remove the ink layer and the conductive layer in contact therewith, thereby causing the areas of the conductive layer on the base material not in contact with the ink layer to form the conductive circuits or patterns.

(b) Description of the Prior Art

Because conductive polymers are provided with intrinsic electrical conductivity, thus, a solution manufacturing process is applied in manufacturing transparent conductive films. Compared to general existing transparent conductive films manufactured using metal oxide compounds, such as ITO (indium tin oxide) films, conductive polymers have the advantages of relatively low material cost and production cost. However, the solid content of the conductive polymer solutions cannot be excessively high, otherwise stability of the conductive polymer solution is reduced. Because solution viscosity is low, thus, it is not suitable for forming designated conductive circuits and patterns. If the formula composition of the conductive polymer solution is revised to provide it with a higher viscosity, then its transparancy, electrical conductivity, water resistance or weathering resistance characteristics would be easily sacrificed or reduced. Hence, related industries have an urgent need for a structure and manufacturing method using conductive polymer solutions with low viscosity to form transparent conductive circuits and patterns.

Current techniques using conductive polymer solutions to form transparent conductive circuits and patterns include laser cutting methods, which is applied by using laser in cutting and forming the patterns. However, in practice, because of the considerably high cost and low speed of using laser equipment, it does not meet with the mass-production requirements of industries. In respect of another manufacturing method, e.g. the plasma etching method, which is applied by using mask material to protect the conductive circuits and patterns requiring to be left behind, while removing the unwanted conductive polymer areas, thereby leaving behind the transparent conductive circuits and patterns. However, cost of the plasma equipment applied in such method is high and the etching speed is slow, and thus similarly does not meet with actual mass-production requirements of industries. Yet another method is an ink-jet method, which is applied by using a piezo or thermo-bubble method to spray a conductive polymer solution in water-drop from through a print head onto the surface of a base material, thereby forming conductive circuits or patterns from a large quantity of ink drops. However, apart from the shortcomings of this method including slow speed of inkjet printing and the print head easily becoming clogged, the uniform quality problems for the conductive circuits or patterns being formed, smoothness of ink spots for the edge lines and ink distribution make it difficult to meet with actual mass-production requirements of speed and quality demanded by industries.

In addition, U.S. Pat. No. 7,749,684B2 filed by Dai Nippon Printing Co., Ltd. discloses a method using the principles of a photosensitive catalyst and surface tension difference to form the required functional circuits and patterns. However, uniformity requirement of the functional circuits and patterns formed using this method is extremely difficult to control. Moreover, because of the numerous limitations of the principles required to form the functional circuits and patterns regarding surface tension, liquid viscosity, and so on, of the functional coating, restrictions are imposed on the composition and properties of the functional coating. Hence, it is difficult to produce conductive circuits and patterns conforming to industrial requirements.

In view of the above shortcomings, the present invention provides the composition of a conductive polymer to form transparent conductive circuits and patterns in an advantageous and convenient manufacturing method, which can perform uniformity and high resolution of the transparent conductive circuits and patterns provided with the advantage of fast production. Accordingly, in light of this, the inventor of the present invention, having accumulated years of experience in related arts, and through continuous research and experimentation, has endeavored to provide an improved structure and manufacturing method for transparent conductive circuits which will effectively reduce the manufacturing cost and increase the production efficiency.

### SUMMARY OF THE INVENTION

The primary objective of the present invention is to provide a structure and manufacturing/pattern forming method of transparent conductive circuits, comprising: a base material, ink layer provided with the characteristics of absorbing conductive polymer liquid and a conductive layer composed of conductive polymer coating. The ink layer is attached to the surface of the base material to form the required circuits or patterns, and either heat energy or radiation is applied to accelerate drying and hardening of the ink. The entire conductive layer, having an area larger than that of the aforementioned ink layer, is applied to cover the ink layer and the base material not covered with ink. The areas of conductive layer on the surface of the base material not in contact with the conductive layer are provided with electrical conductivity. Accordingly, the required conductive circuits or patterns are formed on the base material.

Another objective of the present invention is to provide a structure, whereby the aforementioned conductive layer is first attached to the surface of the base material, and then the ink layer is attached to the surface of the conductive layer to form the required non-conductive areas. After which either heat energy or radiation is applied to accelerate drying and hardening of the ink. The areas relative to the conductive layer on the surface of the base material and not in contact with the ink layer are provided with electrical conductivity. Accordingly, the required conductive circuits or patterns are formed on the base material.

In the aforementioned structure, the conductive layer may be further provided with a removal fluid having polar characteristics. The removal fluid is a polar liqud such as water (H₂O) and ethyl alcohol (C₂H₅OH). The removal fluid is applied to remove the ink layer and the conductive layer areas in contact with the ink, thereby causing the conductive layer areas on the base material not in contact with the ink layer to form circuits or patterns provided with electrical conductivity, or causing the ink layer positioned on the base material to produce a chemical effect through contact with the conductive layer areas, thereby further substantially increasing electrical resistivity of the conductive layer areas in contact with the ink layer, thus locally changing the electrical conductivity of the conductive layer areas on the base material, and causing the designated conductive layer areas not in contact with the ink layer to form conductive circuits or patterns provided with electrical conductivity on the base material.

Yet another objective of the present invention is to provide a manufacturing/pattern forming method of transparent conductive circuits. The specific implementation steps are as follows:

a) Attach ink layer to predetermined areas not requiring electrical conductivity on the surface of a base material, the ink being provided with the characteristics of absorbing conducting polymer liquid, which, after solidification, can be removed using removal fluid provided with polar characteristics;

b) Use either heat energy or radiation to accelerate solidification of the aforementioned ink layer;

c) Cover the surface of the ink layer and predetermined areas requiring electrical conductivity of the aforementioned base material with a conductive layer composed of a conductive polymer coating, and implement solidification thereof; and

d) Use a removal fluid provided with polar characteristics to remove the ink layer and the conductive layer areas in contact therewith, the conductive layer areas remaining on the surface of the base material not in contact with the ink layer as formed are the conductive circuits provided with electrical conductivity.

In addition to the aforementioned implementation steps, the manufacturing/pattern forming method of the present invention further provides other specific implementation steps, described as follows:

a) Cover the surface of a base material with a conductive layer composed of a conductive polymer coating, and solidify it;

b) Use a removal fluid provided with polar characteristics to remove the ink layer attached to the surface of the conductive layer predetermined not to require electrical conductivity, thereby transforming the conductive layer in contact with the ink layer into non-conductive areas that remain on the base material without providing electrical conductivity;

c) Use either heat energy or radiation methods to accelerate solidification of the aforementioned ink layer, the conductive layer areas not in contact with the ink layer on the surface of the base material are provided with electrical conductivity; and

d) Use a removal fluid provided with polar characteristics to remove the aforementioned ink layer, the areas of the conductive layer in contact with the ink is formed with non-conductive areas, and the areas of the conductive layer not in contact with the ink layer is formed with conductive circuits provided with electrical conductivity.

The total area of the aforementioned ink layer is smaller than that of the conductive layer, and either a printing or developing method is used to attach and harden the ink layer to predetermined areas not requiring conductivity.

The aforementioned ink layer attached to the surface of the base material enable increasing electrical resistivity of the conductive layer areas in contact therewith, reaching a value at least 100 times higher than the original resistivity of the conductive layer, to the extent of the conductive layer being non-conductive.

The aforementioned conductive polymer coating contains an intrinsic conductive polymer, and at least comprises a conductive polymer including poly (3,4-ethylenedioxythiophene) (PEDOT) and or pyrroles.

The aforementioned removal fluid is a removal fluid provided with polar characteristics, which enables removing the ink layer and the conductive layer areas in contact therewith. Moreover, the removal fluid is used to increase flatness of the conductive base material, while at the same time reducing overall thickness.

The aforementioned removal fluid provided with polar characteristics can further remove areas of the conductive layer covered by the aforementioned ink layer.

The aforementioned removal fluid provided with polar characteristics is a solution that will not reduce electrical conductivity of the conductive layer in contact with the ink after dissolving and stripping the ink layer.

In the structure and manufacturing/pattern forming method of the aforementioned transparent conductive circuits the ink layer is a radiation curable ink, including UV (ultraviolet) hardening ink layer, and radiation is used to irradiate the ink and accelerate drying and hardening thereof. The radiation used is either ultraviolet rays, visible light or an electron beam.

In the structure and manufacturing/pattern forming method of the aforementioned conductive base material, formation methods of the ink layer include developing methods, lithographic printing or screen printing, and either heat energy or radiation irradiation is used to harden the ink layer. Moreover, the radiation used is ultraviolet rays, visible light or an electron beam, and the heat energy used is either a hot air or infrared rays.

In the structure and manufacturing/pattern forming method the aforementioned transparent conductive circuits, the base material used is either transparent PET (polyethylene terephthalate), PC (polycarbonate), PEN (polyethylene naphthalate), PI (polyimide), acrylic, COC (cyclic olefin copolymer), coating or glass.

In the structure and manufacturing/pattern forming method of the aforementioned transparent conductive base material, the ink layer contains fluorescence material, fluorescence optical brighter or pigment.

In the structure and manufacturing/pattern forming method of the aforementioned transparent conductive circuits, the conductive layer contains a surfactant and at least a binder. The binder further contains at least an UV absorbent or light stabilizing agent. The binder further contains at least one of PU (polyurethane), polyester or acrylic.

In the structure and manufacturing/pattern forming method of the aforementioned transparent conductive circuits, when the conductive polymer of the conductive layer is poly(3,4-ethylenedioxythiophene) (PEDOT), then it further comprises at least a polyacid, such as PSS (polystyenesulfonate). The conductive polymer layer further comprises at least an either silane or a coupling agent. Moreover, electrical resistivity of the conductive layer on the surface of the transparent base material is lower than 2,000 ohm/square. Penetration rate of visible light (380 nm˜750 nm) of the conductive layer is above 65%.

In the structure and manufacturing/pattern forming method of the aforementioned transparent conductive circuits, the conductive layer is formed using one of the following methods: Wire Bar Method, Roller Coating Method, Slot Die Coating, Screen Printing, Spin Coating Method, Knife Over Coating “Gap Coating” and Spray Method.

In the structure and manufacturing/pattern forming method of the aforementioned transparent conductive circuits, the method does not need to use the traditional complex, polluting Chemical Etch Method, as well as being faster than forming methods using high-cost laser equipment and plasma etching methods to form the conductive circuits and patterns. Moreover, the method provides high quality reliability compared to methods used to form the circuits and patterns by a surface tension difference method using a photocatalyst. Furthermore, compared to using ink-jet methods, the present invention is fast, and provides high uniformity and high quality. In particular, the present invention can use functional coatings of low viscosity, such as aqueous conductive polymer coating of low viscosity, to form fine transparent conductive circuits and patterns. Hence, the present invention is able to replace traditional expensive transparent conductive oxide compound thin films using oxide compounds such as indium tin oxide (ITO) and etching manufacturing/pattern forming methods.

To enable a further understanding of said objectives and the technological methods of the invention herein, a brief description of the drawings is provided below followed by a detailed description of the preferred embodiments.

### BRIEF DESCRIPTION OF THE DRAWINGS

FIG. 1 is an elevational structural schematic view of a first embodiment of the present invention.

FIG. 2 is an elevational structural schematic view of a second embodiment of the present invention.

FIG. 3 is a cross-sectional schematic view of the first embodiment of the present invention.

FIG. 4 is a cross-sectional schematic view of the second embodiment of the present invention.

FIG. 5 is a cross-sectional schematic view of the third embodiment of the present invention.

FIG. 6 is a cross-sectional schematic view of the fourth embodiment of the present invention.

FIG. 7 is a flow chart of an embodiment of a manufacturing/pattern forming method (1) of the present invention.

FIG. 8 is a flow chart of an embodiment of a manufacturing/pattern forming method (2) of the present invention.

### DETAILED DESCRIPTION OF THE PREFERRED EMBODIMENTS

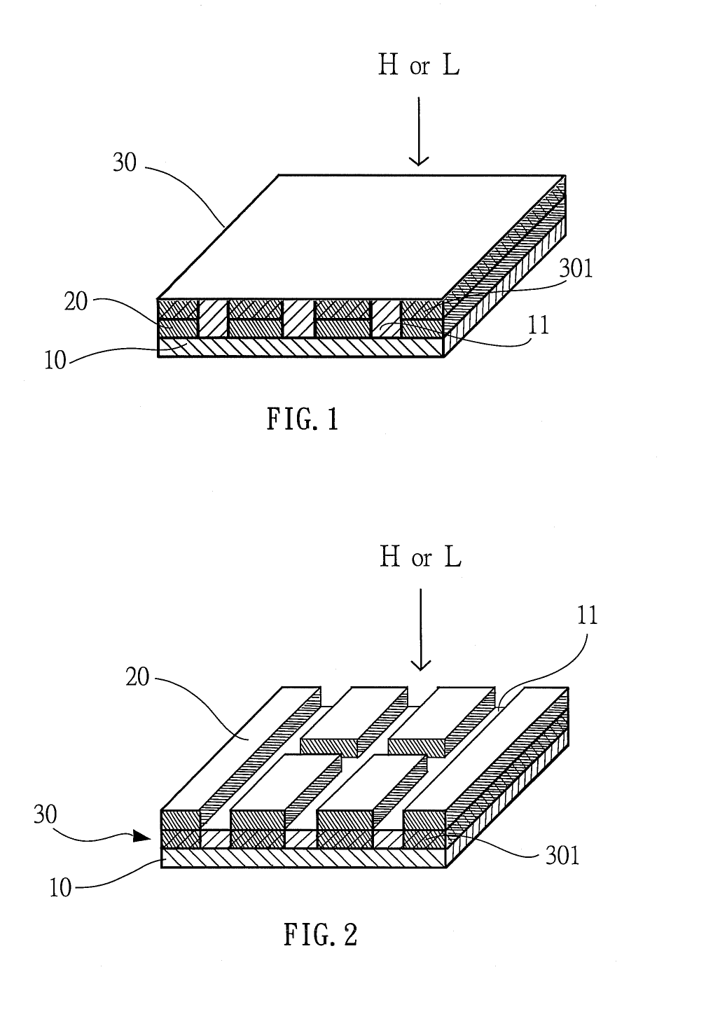

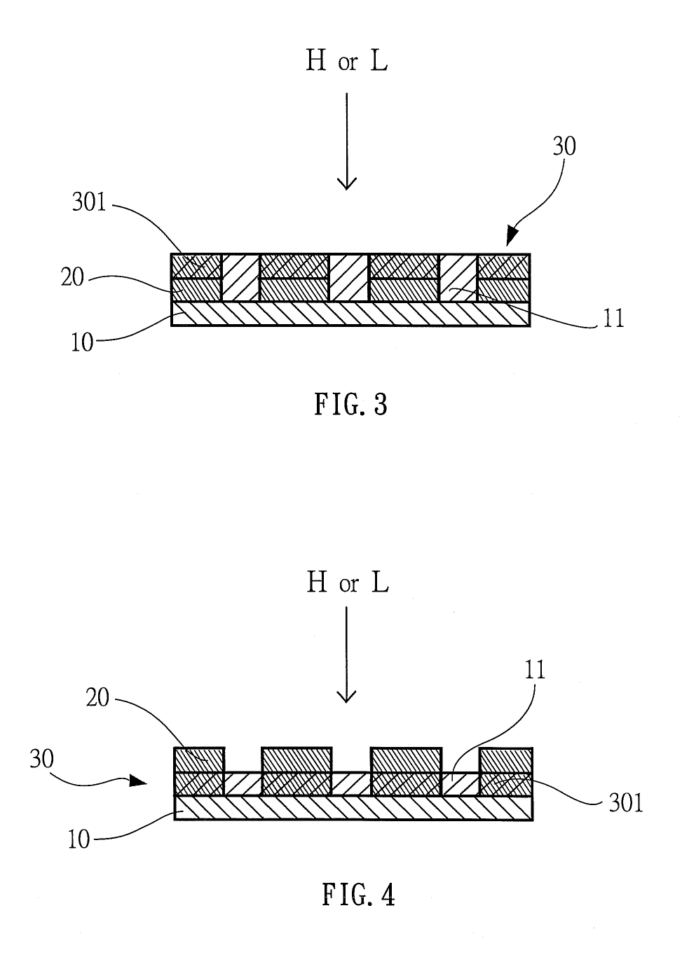

Referring to FIG. 1 and FIG. 3, which show the first embodiment of the present invention, primarily comprise a base material 10, ink layer 20 and a conductive layer 30, wherein, the base material 10 comprises PET, PC, PEN, PI, acrylic, a coating, COC or glass. The ink layer 20 is provided with the characteristics of absorbing conductive polymer liquid. After solidification, the ink layer 20 can be dissolved or swelled in a polar liquid, such as water (H₂O) and ethyl alcohol (C₂H₅OH). The ink layer 20 and the conductive layer 30 further contain fluorescence material, optical brighter or pigment to strengthen optical characteristics and identification, and is attached to the surface of the base material 10 to form the required circuits 11, namely predetermined conductive areas. The ink layer 20 is a transparent ink layer which is soluble in polar liquid. Forming method of the ink layer 20 is applied by either lithographic printing or screen printing, and heat energy H (including hot air or infrared rays) or radiation L can be applied to accelerate drying and hardening of the ink layer 20, thereby enabling attachment to the surface of the transparent base material 10. The aforementioned radiation L includes ultraviolet rays, visible light or an electron beam.

The area of the conductive layer 30 is basically larger than that of the ink layer 20, and its entire area covers the surface of the ink layer 20 and the predetermined non-conductive areas where the ink layer 20 have not been attached. The conductive polymer coating of the conductive layer 30 contains an intrinsic conductive polymer, which at least includes Poly(3,4-ethylenedioxythiophene) (PEDOT) and Pyrrols. The aforementioned ink layer 20 attached to the surface of the base material 10 is applied to increase electrical resistivity of conductive layer 30 in contact therewith so as to generate at least more than 100 times higher than the original resistivity of the conductive layer 30, to the extent of being non-conductive, such that an non-conductive areas 301 is formed.

The embodiment is focused on having a conductive polymer solution composed of a conductive organic polymer containing poly(3,4-ethylenedioxythiophene) (PEDOT) uniformly coated onto a part of or the complete surface of the aforementioned base material 10 and the ink layer 20 on the base material 10 applied by using a method such as a Wire Bar method or Slot Die Coating. After drying for 10 minutes at 120° C., a Four-Pin Method resistivity meter is used to measure the PET thin film conductive polymer conductive layer (beneath the conductive layer 30 where there is no ink), and its original resistivity is 210 □/square (2.1×10² □/square), after deducting the 93-94% transmittance of the original base material of the transparent base material 10, then the penetration rate of visible light for the conductive layer 30 is 91-93%.

The ink-covered surface is formed by ink layer 20 on the surface of the base material 10 at areas other than the conductive circuits 11 requiring electrical conductivity. The areas relative to the ink layer 20 on the surface of the base material 10 where has not been in contact with the conductive layer 30 are provided with electrical conductivity, thereby forming the required conductive circuits 11 on the base material 10.

Referring to FIG. 2 and FIG. 4, which show a second embodiment of the present invention, the differences compared to the first embodiment are that the entire area of the aforementioned conductive layer 30, which is basically larger than that of the ink layer 20, is made to cover the surface of the base material 10, and then the ink layer 20 are attached to the surface of the conductive layer 30, thereby enabling the ink layer 20 to increase electrical resistivity of the conductive layer 30 in contact therewith. Other areas of the surface of the conductive layer 30 not covered by the ink layer 20 form the required conductive circuits 11, which is applied by either heat energy H or radiation L to accelerate drying, reacting or hardening of the ink layer 20, thereby increasing electrical resistivity of the areas of the conductive layer 30 in contact therewith to be at least more than 100 times higher than the original resistivity of the conductive layer 30, to the extent of being non-conductive. The conductive layer 30 comprises a polymer coating composed of conductive organic polymers containing either Poly(3,4-ethylenedioxythiophene) (PEDOT) or Pyrrols. The aforementioned ink layer 20 attached to the surface of the base material 10 is capable of increasing electrical resistivity of the conductive layer 30 in contact with the underneath of the ink layer 20 to be at least more than 100 times higher than the original resistivity of the conductive layer 30, to the extent of being non-conductive, such that the non-conductive areas 301 is formed.

In the second embodiment, a conductive polymer solution made up of a conductive organic polymer containing poly(3,4-ethylenedioxythiophene) (PEDOT) is uniformly coated onto a part of or the complete surface of the aforementioned transparent plastic base material 10 using a Wire Bar method or Slot Die Coating, Resistivity of the PC thin film conducting polymer layer is measured to be 220 □/square using a Four-Pin Method resistivity meter, and electrical resistivity of the areas of the conductive layer 30 in contact with the ink layer 20 is substantially increased approximately 1,000,000 times to around 5×10⁹ □/square,thereby transforming the areas into the non-conductive areas 301.

The areas of the conductive circuits 11 relative to the conductive layer 30 on the surface of the base material 10 where has not been in contact with the ink layer 20 maintain their original electrical conductivity, thereby forming the required conductive circuits 11 on the base material 10. Because the ink layer 20 cover the areas other than the required conductive circuits 11 on the surface of the conductive layer 30 to form ink-covered surfaces, the areas of the conductive circuits 11 relative to the ink layer 20 where has not been in contact with the conductive layer 30 maintain electrical conductivity, thereby forming the required conductive circuits 11 on the base material 10.

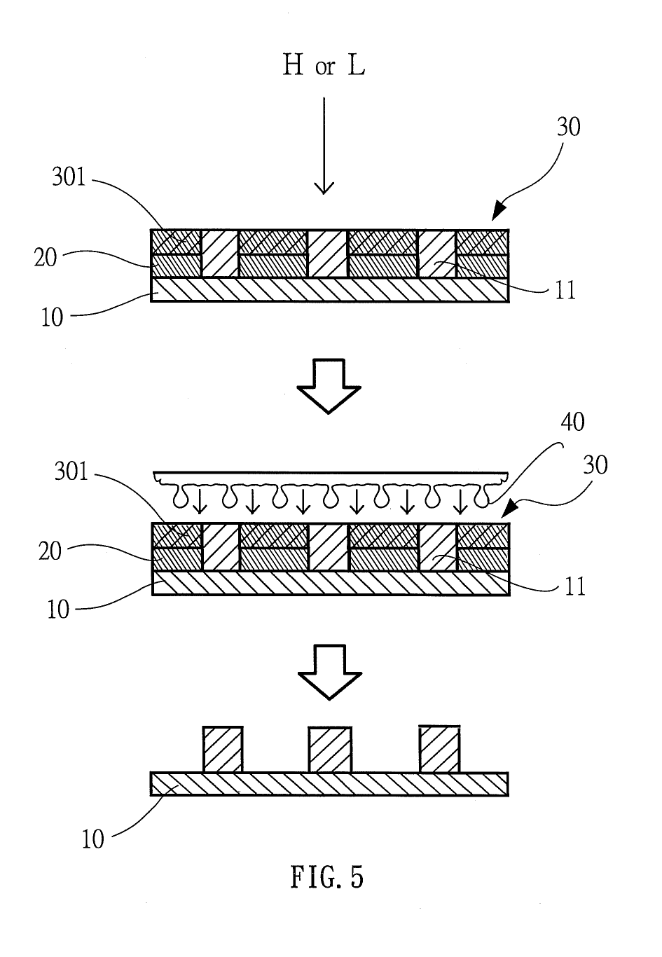

Referring to FIG. 5, which shows a third embodiment of the present invention, the differences compared to the aforementioned embodiments are that the aforementioned ink layer 20 on predetermined non-conductive areas are formed on the predetermined surface of the base material 10, heat energy H or radiation L is further applied to cause solidification thereof. The conductive layer 30 is then made to cover the surface of the ink layer 20 and the predetermined areas of the conductive circuits 11 requiring electrical conductivity, and heat energy H or radiation L is further applied to accelerate drying and solidification of the conductive layer 30 and the ink layer 20.

The third embodiment is applied by uniformly coating a conductive polymer solution composed of a conductive organic polymer containing poly(3,4-ethylenedioxythiophene) (PEDOT) onto part of or the complete surface of the aforementioned transparent base material 10 and the surface of the ink layer 20 on the base material 10 using a Wire Bar method or a Slot Die Coating method. After drying at 120° C. for 10 minutes, a Four-Pin Method resistivity meter is applied to measure the conductive polymer conductive layer (beneath the conductive layer having no ink) on the PET thin film. Its originality resistivity is 210 □/square (2.1×10² □/square), after deducting the original 93-94% transmittance of the base material of the transparent base material 10, then the visible light penetration rate of the conductive layer 30 is 91-93%.

In the third embodiment, the conductive layer 30 and the areas of the surface thereof in contact with the ink layer 20 forming the non-conductive areas 301 can be further removed physically by the removal fluid 40. The removal fluid 40 is a polar liquid, such as water (H2O) and ethyl alcohol (C₂H₅OH) which can at the same time remove the ink layer 20 and the non-conductive areas 301. The ink layer 20 on the surface of the base material 10 and the areas not yet covered by the conductive layer 30 assume an indented form, and the entire conductive layer 30 is attached to the ink layer 20 and the surfaces of the areas of the circuits 11 predetermined to require electrical conductivity. Accordingly, the conductive layer 30 further fills the cavity areas. After the removal fluid 40 is applied to remove the ink layer 20 and the conductive layer 30 at the same time, then the conductive layer 30 on the surface of the base material 10 where has not been in contact with the ink layer 20 forming the circuits 11. In addition, after using the removal fluid 40, the conductive circuits 11 assumes protrude-out in shape relative to the base material 10.

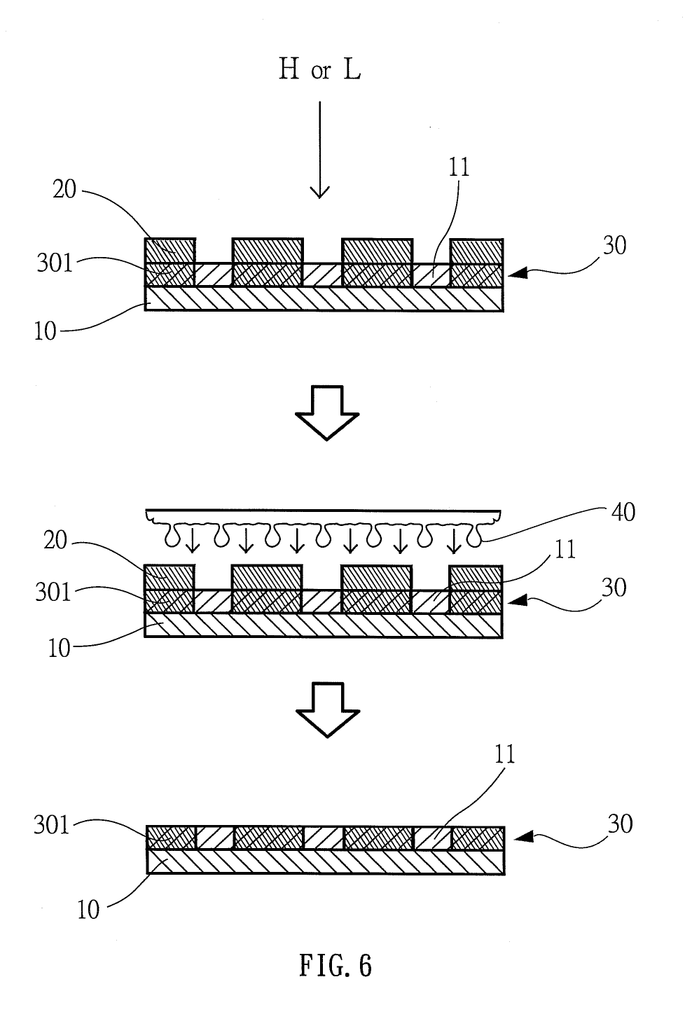

Referring to FIG. 6, which shows a fourth embodiment of the present invention, the aforementioned conductive layer 30 having an area basically larger than that of the ink layer 20 is made to entirely cover and be attached to the surface of the base material 10, and then the ink layer 20 is formed by attaching to the predetermined areas not requiring conductivity on the surface of the conductive layer 30 using a partial attachment means, after which either heat energy H or radiation L is applied to accelerate drying, reacting or hardening of the ink layer 20. Moreover, electrical resistivity of the areas of the conductive layer 30 in contact with the underneath of the ink layer 20 is substantially increased to at least more than 100 times that of the original resistivity of the conductive layer 30, to the extent of being non-conductive, such that the non-conductive areas 301 is formed.

In the fourth embodiment, a conductive polymer solution composed of a conductive organic polymer containing poly(3,4-ethylenedioxythiophene) (PEDOT) is applied to have the surface of a transparent PC thin film uniformly coated by using a Wire Bar method or a Slot Die Coating method. After drying the aforementioned conductive polymer solution at 120° C. for 10 minutes, then the surface of the transparent PC thin film forms a conductive layer. A Four-Pin Method resistivity meter is used to measure resistivity of the conductive polymer layer on the surface of the PC thin film, obtaining a resistivity of 220 □×10² □/square.

The ink layer 20 as disclosed in the fourth embodiment can be further removed using the removal fluid 40 provided with polar characteristics. The removal fluid 40 is a polar liquid such as water (H₂O) or ethyl alcohol (C₂H₅OH) or an intermixture containing different polar liquids, which is applied to remove the ink layer 20. Because a chemical reaction occurs at the areas of the ink layer 20 in contact with the conductive layer 30, thus, the electrical resistivity of the areas of the conductive layer 30 on the transparent base material 10 in contact with the underneath of the ink layer 20 is substantially increased. Accordingly, the required circuits 11 are formed on the areas where the conductive layer 30 has not been in contact with the ink layer 20 on the base material 10.

In the fourth embodiment, since the areas of the conductive layer 30 in contact with the ink layer 20 has been transformed into the non-conductive areas 301, when the removal fluid 40 is applied to remove the ink layer 20 in contact with the conductive layer 30, the non-conductive areas 301 having no electrical conductivity properties is still remained on the base material 10. Correspondingly, the areas of the conductive layer 30 not in contact with the ink layer 20 are provided with electrical conductivity, thereby forming the required conductive circuits 11 on the base material 10. Moreover, after the removal process using the removal fluid 40, the conductive circuits 11 assume flat in shape relative to the entire base material 10.

In addition, the aforementioned removal fluid provided with polar characteristics is capable of further removing the conductive layer areas covered by the aforementioned ink layer.

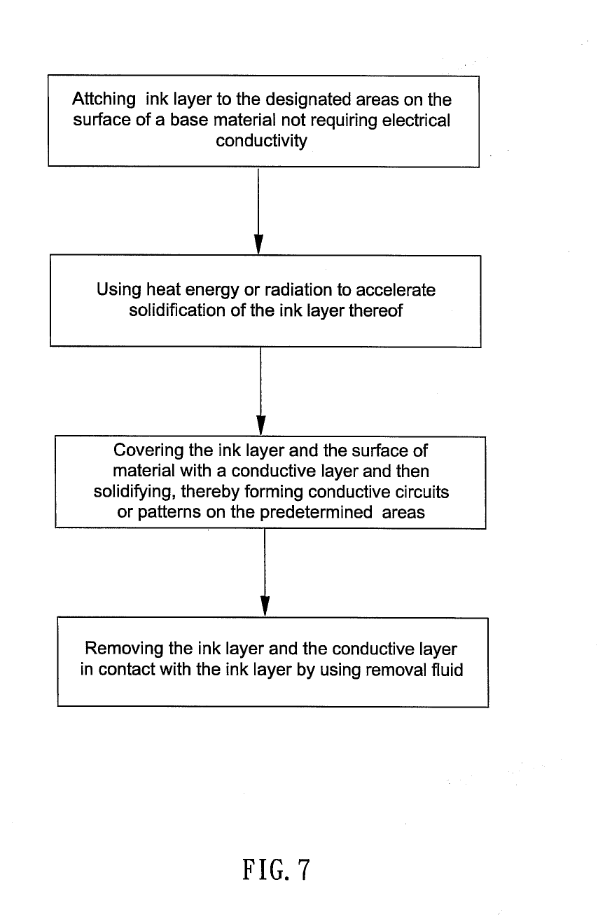

Referring to FIG. 7, which shows a flow chart for an embodiment of the manufacturing/pattern forming method (1) of the present invention, comprising the following steps:

a) Attach the ink layer 20 to the predetermined areas on the surface of the base material 10 not requiring electrical conductivity using either a printing method or developing method; the ink layer 20 having the characteristics of absorbing conductive polymer liquid which after solidification can be removed using a removal fluid having the polar characteristics;

b) Irradiate the aforementioned ink layer 20 with either heat energy H or radiation L to accelerate solidification of the ink layer 20;

c) Cover the ink layer 20 and the surfaces requiring the conductive circuits 11 with the conductive layer 30 having an area basically larger than that of the aforementioned ink layer 20, and implement drying and solidification thereof; the conductive layer 30 being composed of a conductive polymer coating containing an intrinsic conductive polymer. The ink layer 20 attached to the surface of the base material 10 enables increasing electrical resistivity of the areas of the conductive layer 30 in contact with the surface thereof to at least more than 100 times higher than the original resistivity of the conductive layer 30, to extent of being non-conductive such that a non-conductive areas 301 is formed. The areas of the conductive layer 30 not in contact with the ink layer 20 are provided with electrical conductivity, thereby forming the conductive circuits 11; and

d) Remove the ink layer 20 and the conductive layer 30 in contact with the ink layer 20 phsysically using the removal fluid 40 provided with the polar characteristics, leaving behind the conductive layer 30 on the surface of the base material 10 not in contact with the ink layer 20, namely the conductive circuits 11 provided with electrical conductivity.

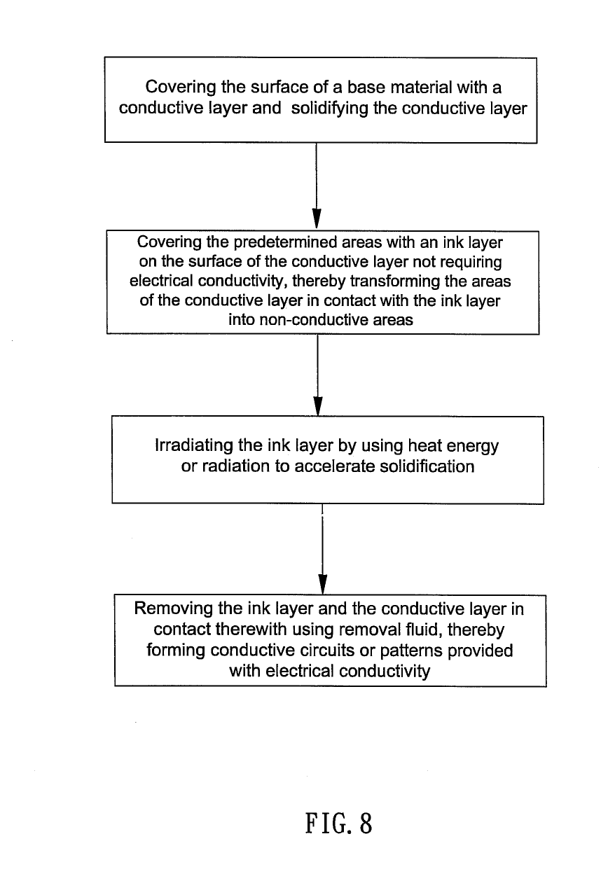

Referring to FIG. 8, which shows a flow chart for an embodiment of the manufacturing/pattern forming method (2) of the present invention, comprising the following steps:

a) Cover the surface of the base material 10 with the conductive layer 30 composed of a conductive polymer coating, and implement drying and solidification thereof. The conductive polymer coating contains an intrinsic conductive polymer;

b) Attach the polar liquid soluble ink layer 20 to the predetermined areas of the surface of the conductive layer 30 not requiring electrical conductivity using either a printing method or developing method; the ink layer 20 having an area basically smaller than that of the aforementioned conductive layer 30. Accordingly, the areas of the conductive layer 30 in contact with the ink layer 20 are transformed into the non-conductive areas 301 provided with no electrical conductivity and positioned above the base material 10;

c) Use either heat energy or radiation to accelerate drying, reacting or hardening of the aforementioned ink layer 20 to form the conductive circuits 11, and increase electrical resistivity for the areas of the conductive layer 30 in contact with the ink layer 20 to at least more than 100 times higher than the original resistivity of the conductive layer 30, to the extent of being non-conductive, such that the non-conductive areas 301 is formed. The areas relative to the conductive layer 30 on the surface of the base material 10 not in contact with the ink layer 20 form the conductive circuits 11 predetermined to require conductivity; and

d) Use the removal fluid 40 provided with polar characteristics to remove the aforementioned ink layer 20; the areas of the conductive layer 30 in contact with the ink layer 20 forming the non-conductive areas 301. Relative to the non-conductive areas 301 on the surface of the base material 10, the areas of the conductive layer 30 not in contact with the ink layer 20 whereby forming the conductive circuits 11 provided with electrical conductivity, while at the same time, flatness of the surface of the conductive layer 30 is increased, and thickness of the entire transparent conducting structure is also reduced.

The removal fluid 40 mentioned in each of the aforementioned embodiments is a solution that will not reduce electrical conductivity of areas in contact with the conductive layer 30 after dissolving and stripping off the ink layer 20.

In the embodiments (1) and (2) for the manufacturing/pattern forming method of the aforementioned transparent conductive circuits, the conductive layer contains a surfactant and at least a binder. The binder further contains at least either a UV absorbent or light stabilizing agent. The binder further contains at least either PU, polyester or acrylic. When the conductive polymer of the conductive layer is poly(3,4-ethylenedioxythiophene) (PEDOT), then it further comprises at least a polyacid, such as PSS (polystyenesulfonate).

The conductive polymer layer further comprises at least either silane or a coupling agent. Moreover, electrical resistance of the conductive layer on the surface of the transparent base material is lower than 2,000 ohm/square. Penetration rate of visible light (380 nm˜750 nm) of the conductive layer is above 65%. Methods used to form the conductive layer includes a Wire Bar Method, Roller Coating Method, Slot Die Coating, Spin Coating Method, Knife Over Coating “Gap Coating” or Spraying.

Application areas of the structure and manufacturing/pattern forming method of transparent conductive circuits of the present invention include at least Transparent Conductive Film (TCF), liquid-crystal display (LCD), heat-isolation glass, Touch Panel, Thin Film Resistor, Thin Film Transistor, Light-Emitting Device, Solar Cell and Printed Electronics.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. A structure of transparent conductive circuits, comprising:
a base material;
a transparent ink layer provided with absorbing conductive polymer liquid characteristics, the ink layer is attached to a predetermined area on a surface of the base material not requiring electrical conductivity, and either heat energy or radiation is applied in accelerating solidification of the ink;
a conductive layer covers the ink layer and the predetermined area requiring electrical conductivity on the surface of the base material; the conductive polymer coating contains an intrinsic conductive polymer, and the ink layer attached to the surface of the base material thereby increasing electrical resistivity of the conductive layer in contact therewith to be at least more than 100 times higher than the original resistivity of the conductive layer, to the extent of being non-conductive; the area relative to the conductive layer on the surface of the base material where has not been in contact with the ink layer is provided with electrical conductivity thereby forming the required conductive circuit on the base material.

2. A structure of transparent conductive circuits, comprising:
a base material;
a conductive layer attached to a surface of the base material; the conductive polymer coating contains an intrinsic conductive polymer;
a transparent ink layer soluble in a polar liquid; the transparent ink layer is attached to area on the surface of the conductive layer predetermined not to require electrical conductivity, and either heat energy or radiation is applied to accelerate drying and solidification of the ink layer, as well as increasing electrical resistivity of the conductive layer in contact with the ink layer to be at least more than 100 times higher than the original resistivity of the conductive layer, to the extent of being non-conductive; the area relative to the conductive layer on the surface of the base material where has not been in contact with the ink layer is provided with electrical conductivity thereby forming required conductive circuit on the base material.

3. A pattern forming method of transparent conductive circuits, comprising steps of:
a) attaching an ink layer to a predetermined area on a surface of a base material not requiring electrical conductivity; wherein the ink layer can be removed by using a removal fluid having polar characteristics;
b) irradiating the ink layer with either heat energy or radiation to accelerate solidification of the ink layer;
c) covering the surface of the ink layer and the area on the base material predetermined to require electrical conductivity with a conductive layer, and implement drying and solidification thereof; the conductive polymer coating contains an intrinsic conductive polymer; and
d) removing the ink layer and the conductive layer in contact with the ink layer physically by using a removal fluid provided with the polar characteristics, leaving behind the conductive layer on the surface of the base material not in contact with the ink layer, thereby forming the conductive circuits provided with electrical conductivity.

4. A pattern forming method of transparent conductive circuits, comprising steps of:
a) covering a surface of a base material with a conductive polymer coating, and implement drying and solidification thereof; the conductive polymer coating contains an intrinsic conductive polymer;
b) attaching an ink layer to the predetermined area of the surface of a conductive layer not requiring electrical conductivity, wherein the ink layer can be removed by using a removal fluid having polar characteristics; accordingly, the areas of the conductive layer in contact with the ink layer are transformed into non-conductive areas provided with no electrical conductivity and positioned on the base material;
c) using either heat energy or radiation to accelerate solidification of the ink layer and increase electrical resistivity of the area of the conductive layer in contact with the ink layer to at least more than 100 times higher than the original resistivity of the conductive layer, to the extent of being non-conductive, the area relative to the conductive layer on the surface of the base material not in contact with the ink layer is provided with electrical conductivity; and
d) using the removal fluid provided with polar characteristics to remove the ink layer; wherein, the non-conductive area is formed on the area of the conductive layer in contact with the ink layer and the conductive circuit provided with electrical conductivity is formed on the area of the conductive layer not in contact with the ink layer.

5. The pattern forming method of transparent conductive circuits and pattern according to claim 4, wherein the removal fluid removes the ink layer and the conductive layer in contact with the ink layer.

6. The structure of transparent conducting according to claims 1, wherein the intrinsic conductive polymer comprises either Poly(3,4-ethylenedioxythiophene) (PEDOT) or Pyrrols.

7. The structure of transparent conducting according to claim 2, wherein the intrinsic conductive polymer comprises either Poly(3, 4-ethylenedioxythiophene) (PEDOT) or Pyrrols.

8. The pattern forming method of transparent conducting according to claim 3, wherein the intrinsic conductive polymer comprises either Poly(3,4-ethylenedioxythiophene) (PEDOT) or Pyrrols.

9. The pattern forming method of transparent conducting according to claim 4, wherein the intrinsic conductive polymer comprises either Poly(3,4-ethylenedioxythiophene) (PEDOT) or Pyrrols.

10. The structure of transparent conducting according to claim 1, wherein the conductive layer comprises a surfactant, which further comprises either a UV (ultraviolet) absorber or light stabilizing agent.

11. The structure of transparent conducting according to claim 2, wherein the conductive layer comprises a surfactant, which further comprises either a UV (ultraviolet) absorber or light stabilizing agent.

12. The pattern forming method of transparent conducting according to claim 3, wherein the conductive layer comprises a surfactant, which further comprises either a UV (ultraviolet) absorber or light stabilizing agent.

13. The pattern forming method of transparent conducting according to claim 4, wherein the conductive layer comprises a surfactant, which further comprises either a UV (ultraviolet) absorber or light stabilizing agent.

14. The structure of transparent conducting according to claim 1, wherein the conductive layer comprises a binder, which further comprises PU (polyurethane), polyester or acrylic.

15. The structure of transparent conducting according to claim 2, wherein the conductive layer comprises a binder, which further comprises PU (polyurethane), polyester or acrylic.

16. The pattern forming method of transparent conducting according to claim 3, wherein the conductive layer comprises a binder, which further comprises PU (polyurethane), polyester or acrylic.

17. The pattern forming method of transparent conducting according to claim 4, wherein the conductive layer comprises a binder, which further comprises PU (polyurethane), polyester or acrylic.

18. The structure of transparent conducting according to claims 1, wherein the intrinsic conductive polymer comprises a silane.

19. The structure of transparent conducting according to claim 2, wherein the intrinsic conductive polymer comprises a silane.

20. The pattern forming method of transparent conducting according to claim 3, wherein the intrinsic conductive polymer comprises a silane.

21. The pattern forming method of transparent conducting according to claim 4, wherein the intrinsic conductive polymer comprises a silane.
